(19) United States
(12) Patent Application Publication
(10) Pub. No.: US 2006/0234436 A1
(43) Pub. Date: Oct. 19, 2006

(54) Method of forming a semiconductor device having a high-k dielectric

(76) Inventors: Hsing H. Tseng, Austin, TX (US); Olubunmi O. Adetutu, Austin, TX (US); David C. Gilmer, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/106,797

(22) Filed: Apr. 15, 2005

(51) Int. Cl. H01L 21/8238; H01L 21/336; H01L 21/31

(52) U.S. Cl. 438/216; 438/785; 438/287

(57) ABSTRACT

A metal oxide is formed over a high quality oxide which has been deposited over a substrate. An anneal drives a reaction to form a metal oxysilicon nitride layer which is then used as a part of a gate stack. The novel integration scheme allows for improved scalablity of devices as well as improved leakage currents.

### FIELD OF THE INVENTION

This invention relates generally to the field of semiconductor devices, and more particularly, to the field of processing of semiconductor devices using high-k dielectric films.

### BACKGROUND

A reduction in the gate oxide thickness for CMOS (complementary metal oxide semioconductor) devices is necessary to improve the speed of the devices. However, when the thickness of the gate oxide is decreased, the leakage currents generally increases. Therefore, new materials are currently being investigated to replace the current gate oxide for CMOS devices. Materials that are under consideration include metal oxides, metal silicates, as well as metal silicon oxynitrides, collectively referred to as high-k (high dielectric constant) dielectrics. These materials, due to scaling issues, are required to be ultra-thin, on the order of 10's of angstroms.

Metal silicon oxynitrides are especially attractive for this purpose due to their increased dielectric constant over silicates, their reduction in phase separation over pure silicates as well as their amorphous nature. These materials provide excellent device performance and reliability. In particular, one such metal silicon oxynitride receiving widespread attenttion is HfSiON.

In a typical method of forming a high-k dielectric material over silicon, an interfacial layer of SiOₓ results after post-deposition anneal. This interfacial layer limits the scaling of the high-k material. One method that has been proposed to reduce the interfacial layer, has been to nitridize the silicon substrate prior to the high-k dielectric material deposition. The result of this nitridization has been to merely reduced the interfacial layer thickness and not remove it. It is clear that this approach cannot meet the scaling requirements for future generations of CMOS devices.

In yet another proposed method to integrate high-k dielectric materials while minimizing the interfacial layer, an oxide has been either deposited or grown over the silicon substrate and then etched back to a reduced thickness and followed by a high-k dielectric material deposition. Again, this approach limits the scalability of the overall high-k integration and only serves to minimize the interfacial layer thickness.

Therefore a need exists to successfully integrate the high-k materials while preserving the quality of the interface near the silicon substrate as well as maintaining scaling capabilities.

### BRIEF DESCRIPTION OF THE DRAWINGS

The present invention is illustrated by way of example and is not limited by the accompanying figures, in which like references indicate similar elements.

FIG. 1 illustrates a schematic cross sectional view of a portion of a semiconductor device in which there is a high quality oxide or oxynitride layer formed on a silicon substrate in accordance with an embodiment of the present invention.

FIG. 2 illustrates the semiconductor device of FIG. 1 where the oxide or oxynitride is etched back to a desired thickness in accordance with an embodiment of the present invention.

FIG. 3 illustrates the semiconductor device of FIG. 2 where a layer of metal oxide or a metal nitride is deposited on the silicon substrate in accordance with an embodiment of the present invention.

FIG. 4 illustrates the semiconductor device of FIG. 3 after an anneal to integrate the metal or nitrogen into the underlying oxide or oxynitride layer in accordance with an embodiment of the present invention.

FIG. 5 illustrates the semiconductor device of FIG. 4 after a change in the composition of the oxide or oxynitride layer to a metal silicon oxynitride layer in accordance with an embodiment of the present invention.

FIG. 6 illustrates the semiconductor device of FIG. 5 after an etch process removes the residual metal oxide or metal nitride layer in accordance with an embodiment of the present invention.

FIG. 7 illustrates the semiconductor device of FIG. 6 where an optional anneal can be performed to further improve the quality of the metal silicon oxynitride layer in accordance with an embodiment of the present invention.

FIG. 8 illustrates the semiconductor device of FIG. 7 after formation of gate electrodes and doping of source and drain areas in accordance with an embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE INVENTION

Rather than attempt a removal of oxide over the silicon, incorporation of the oxide into the process is performed. In one aspect, a high quality oxide is deposited on a silicon substrate. The oxide then has a layer of metal nitride deposited over the high quality oxide and the resulting stack is annealed. The anneal serves to create a metal silicon oxynitride layer which has improved scalability and reliablity over conventional gate oxides. The full process is better understood by reference to the FIGs. and the following description.

FIG. 1 includes illustrations of regions of a semiconductor substrate 12 within a semiconductor device 10. The semiconductor substrate 12 can include a monocrystalline semiconductor wafer, or other substrates conventionally used to form electronic devices. A high quality oxide layer 14 is either thermally grown or deposited over the semiconductor substrate using methods known to one of skill in the art. Such deposition methods can include atomic layer deposition (ALD), metal organic CVD (MOCVD), or physical vapor deposition (PVD) methods. In a preferred embodiment the thickness of layer 14, when either thermally grown or deposited, is 50-60 Å. In another embodiment, layer 14 can be thermally grown or deposited to a thickness of preferably 10 Å. Additionally, the oxide layer can be grown by chemical methods including RCA clean, which may include the use of piranha, HF, and SC1 followed by SC2 chemicals. A preferred thickness of layer 14 when chemically grown is 10 Å.

Layer 14 can also be an oxynitride. If the layer 14 is an oxynitride, either thermal growth or deposition can be used. In a similar case to the layer 14 being an oxide, the oxynitride can either be thermally grown or deposited to a thickness of 50-60 Å or to 10 Å depending on the subsequent processing steps.

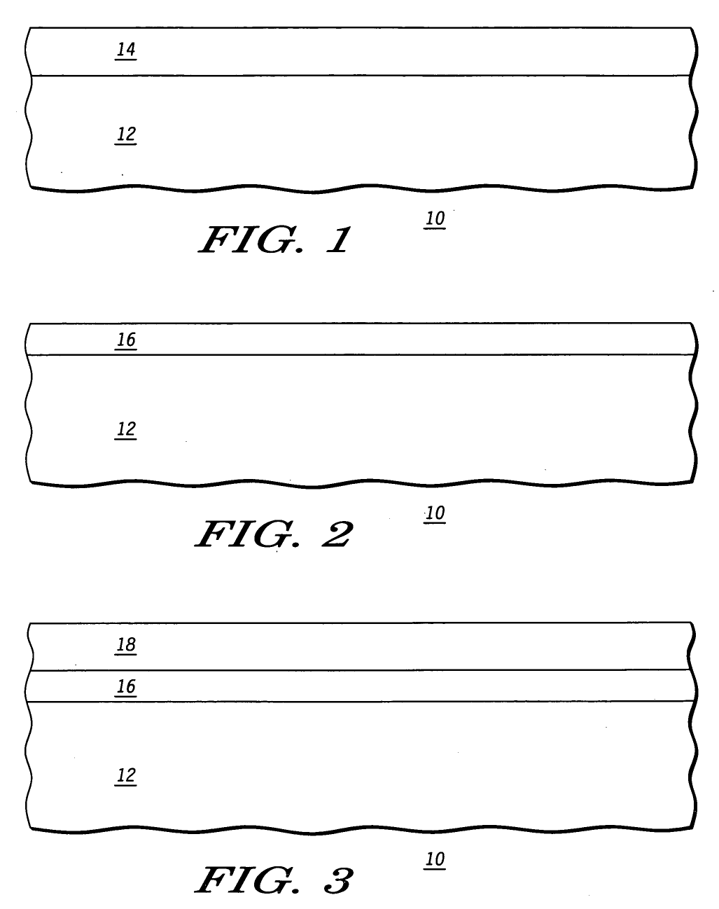

FIG. 2 illustrates the case where the oxide or oxynitride layer is either formed and then removed to a thickness of less than 15 Å and preferably less than 10 Å, resulting in layer 16. The removal may occur by an etchback or any other suitable process. When the layer 14 is thermally grown, deposited, or chemically grown to a thickness of approximately 10 Å no etchback or other removal process would be needed. One of skill in the art would then recognize that layer 14 in FIG. 1 would then be the same as layer 16 in FIG. 2.

After the oxide or oxynitride layer 16 achieves a thickness of less than 15 Å, a layer 18 of metal oxide or metal nitride is deposited as shown in FIG. 3. Layer 18 may be deposited to a thickness of greater than 10 Å and preferably 30 Å. Metal oxide or metal nitride layer 18 can be deposited by MOCVD or ALD techniques as well as PVD techniques. The metal oxides may include HfO₂, ZrO₂, Al₂O₃, La₂O₅, the like, and combinations of the above. The metal nitrides may include WₓN_{y}, TiN, TaN, MOₓN_{y}, the like, and combinations of the above.

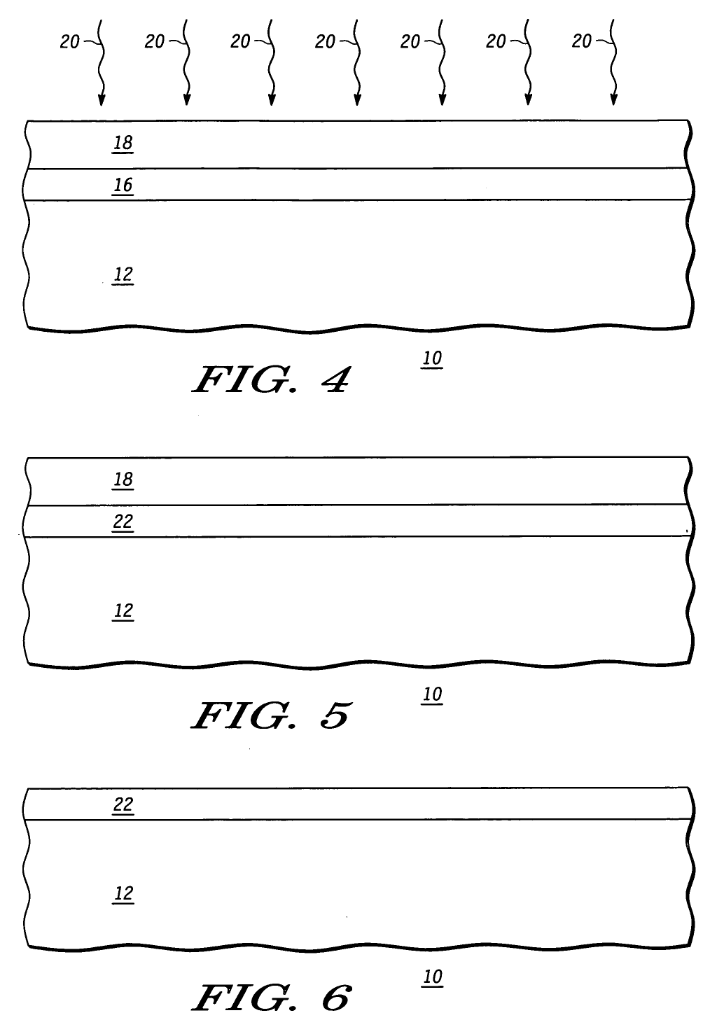

The metal oxide or metal nitride layer 18 is then annealed as shown in FIG. 4 by element 20, in order to integrate the metal or nitrogen into the underlying oxide or oxynitride layer 16. The anneal ambient preferably contains nitrogen and is preferably dry nitrogen or ammonia gas. This is especially important in the case where layer 16 is an oxide and layer 18 is metal oxide. This anneal forms a metal silicon oxynitride layer 22 in FIG. 5. The anneal temperature for dry nitrogen may be greater than 1000° C. The ammonia anneal temperature may be less than 900° C.

In the case where metal nitride layer 18 is over an oxide or oxynitride layer 16, an alternative anneal ambient can include argon or other inert gas. Additionally, the gas anneal temperature, in this case, need not be greater than 1000° C. in order to form the metal silicon oxynitride layer 22 in FIG. 5

The unreacted metal oxide or metal nitride layer 18 is then removed as shown in FIG. 6. This can be accomplished by either dry or wet chemical methods. A dry etch may include HCl gas. A wet etch may include piranha. The etch chemistries are chosen so as little or no effect on the underlying metal silicon oxynitride layer 22.

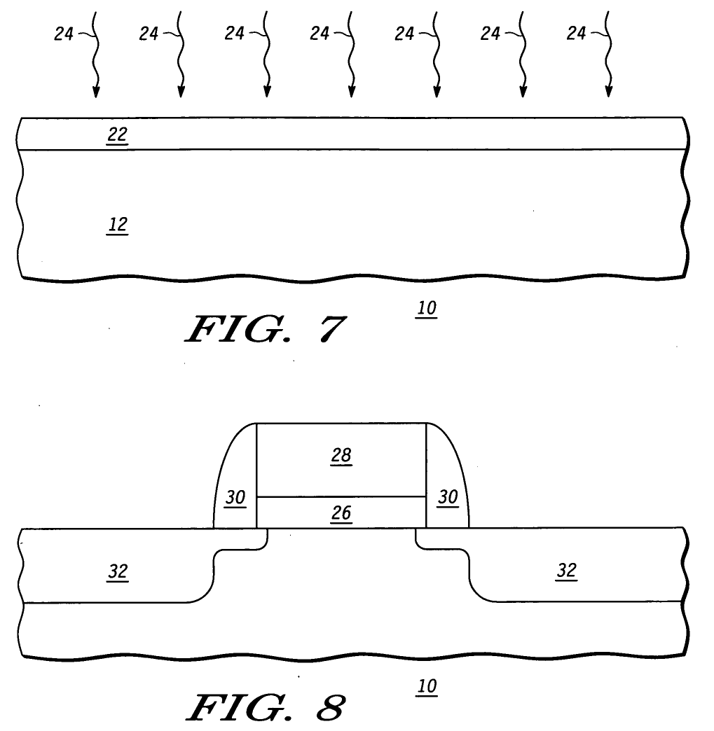

An optional anneal 24 can then be used to improve the metal silicon oxynitride film quality as shown in FIG. 7. The anneal may be argon or other inert gas at a temperature of less than 900° C. After such an anneal, the resulting metal silicon oxynitride layer is represented as layer 26.

Further processing would then be used to build a final semiconductor device as shown in FIG. 8 and includes deposition or formation of layers 28 to 32. A layer of polysilicon or metal gate electrode material 28 is deposited followed by a gate stack etch. A spacer material 30 is then deposited and patterned by typical processing steps. Dopants are then implanted into the substrate in order to form source and drain areas as shown by areas 32. Subsequent processing steps for the remainder of the device formation are typical for one of skill in the art and will not be presented here.

In the foregoing specification, the invention has been described with reference to specific embodiments. However, one of ordinary skill in the art appreciates that various modifications and changes can be made without departing from the scope of the present invention as set forth in the claims below. Certain materials were described and these may be varied. As further alternatives, hafnium oxide was described as the exemplary metal oxide but other high-k dielectrics may be used such as zirconium oxide or other metal oxides such as lanthanum aluminum oxynitride may also benefit from this process. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprise”, “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. The terms “a” or “an”, as used herein, are defined as one or more than one.

Moreover, the terms “front”, “back”, “top”, “bottom”, “over”, “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

What is claimed is:

1. A method of forming a semiconductor device, the method comprising:
providing a semiconductor substrate;
forming a dielectric layer over the semiconductor substrate;
forming a metal-containing material over the dielectric layer, wherein the metal-containing material comprises an element;
incorporating the element from the metal-containing material into the dielectric layer; and
removing at least a portion of the metal-containing material.

2. The method of claim 1, wherein the incorporating the element comprises annealing the dielectric layer and the metal-containing material.

3. The method of claim 1, wherein the incorporating the element occurs while forming the metal-containing material.

4. The method of claim 1, wherein the semiconductor substrate comprises a semiconductor element and the dielectric layer comprises the semiconductor element and oxygen.

5. The method of claim 4, wherein the dielectric layer further comprises nitrogen.

6. The method of claim 1, wherein the element of the metal-containing material is nitrogen.

7. The method of claim 1, wherein the element of the metal-containing material is a metal.

8. The method of claim 1, wherein the removing at least a portion of the metal-containing layer further comprises removing the entire metal-containing layer.

9. The method of claim 1, wherein the metal-containing material comprises Hf, Ti, Ta, or Zr.

10. A method of forming a semiconductor device, the method comprising:
providing a semiconductor substrate;
forming a dielectric layer over the semiconductor substrate;
forming a metal and nitrogen-containing material over the dielectric layer, wherein the material comprises a first element; and
incorporating the first element from the metal and nitrogen-containing material into the dielectric layer.

11. The method of claim 10, further comprising removing at least a portion of the metal and nitrogen-containing material.

12. The method of claim 10, further comprising incorporating a second element into the metal and nitrogen-containing material while incorporaing the first element, wherein the first element is nitrogen and the second element is a metal.

13. The method of claim 10, wherein the incorporating comprises incorporating nitrogen into the dielectric layer.

14. The method of claim 10, wherein the incorporating comprises incorporating a metal into the dielectric layer.

15. A method of forming a semiconductor device, the method comprising:
providing a semiconductor substrate;
forming a dielectric layer over the semiconductor substrate;
forming a material over the dielectric layer, wherein the material comprises a metal;
incorporating the metal from the material into the dielectric layer; and
removing at least a portion of the metal-containing material.

16. The method of claim 15, wherein the material further comprises oxygen.

17. The method of claim 15, wherein the incorporating the metal comprises annealing the dielectric layer and the material.

18. The method of claim 15, wherein the incorporating the metal occurs while forming the material.

19. The method of claim 15, wherein the dielectric layer further comprises nitrogen.

20. The method of claim 1, wherein the removing at least a portion of the metal-containing layer further comprises removing the entire metal-containing layer.
